(19) United States
(12) Patent Application Publication
(10) Pub. No.: US 2006/0098524 A1
(43) Pub. Date: May 11, 2006

(54) Forming planarized semiconductor structures

(76) Inventors: Daniel Xu, Mountain View, CA (US); Tyler Lowrey, West Augusta, VA (US); Jong-Won S. Lee, Sunnyvale, CA (US); Kyu S. Min, San Jose, CA (US); Donghui Lu, San Jose, CA (US); Jenn Chow, Cupertino, CA (US)

Correspondence Address: TROP PRUNER & HU, PC, 8554 KATY FREEWAY, SUITE 100, HOUSTON, TX, 77024, US

(21) Appl. No.: 11/303,417

(22) Filed: Dec. 16, 2005

Related U.S. Application Data
(62) Division of application No. 10/633,881, filed on Aug. 4, 2003.

(51) Int. Cl. G11C 8/02

(52) U.S. Cl. 365/232

(57) ABSTRACT

A planarized surface may be formed by initially forming an aperture through an insulating layer. The insulating layer and its aperture may be conformally coated with a conductive material that ultimately acts as a planarization stop. The conductive material may then be covered with another insulator that fills the remainder of the aperture. Thereafter, the structure may be planarized down to the conductive layer that acts as a planarization stop.

### CROSS-REFERENCE TO RELATED APPLICATIONS

This application is a divisional of U.S. patent application Ser. No. 10/633,881, filed on Aug. 4, 2003.

### BACKGROUND

This invention relates generally to semiconductor fabrication technology and, particularly, to forming planarized conductive structures.

In semiconductor manufacturing operations, it may be desirable to form a generally or substantially planar structure. Particularly, it may be desirable to form plugs that are metallic conductors that extend through holes in dielectrics. Conventionally this is done by simply filling the hole with a metal conductor in a step called tungsten plug. However, filling the hole with a metal conductor may make substantial planarity difficult to achieve because of the different characteristics of the filler material, which may be a metal or other conductive material, and the surrounding material, which may be a dielectric. Chemical mechanical polishing may not be suitable because the ability to polish the metal may be substantially reduced relative to the polishing effect on the surrounding dielectric.

One place where planarized structures may be useful is in connection with phase change memories. Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between different detectable states of local order across the entire spectrum between completely amorphous and completely crystalline states.

Typical materials suitable for such an application include various chalcogenide elements. The state of the phase change materials is also non-volatile. When the memory is set in either a crystalline, semi-crystalline, amorphous, or semi-amorphous state representing a resistance value, that value is retained until reprogrammed, even if power is removed. This is because the programmed value represents a phase or physical state of the material (e.g., crystalline or amorphous).

Thus, there is a need for better ways to form substantially planar structures.

### BRIEF DESCRIPTION OF THE DRAWINGS

FIG. 1 is an enlarged cross-sectional view through one embodiment of the present invention;

FIG. 2 is an enlarged, schematic cross-sectional view of an early stage of manufacture in accordance with one embodiment of the present invention;

FIG. 3 is an enlarged, schematic cross-sectional view at a subsequent stage of manufacture in accordance with one embodiment of the present invention;

FIG. 4 is an enlarged, schematic cross-sectional view at a subsequent stage of manufacture in accordance with one embodiment of the present invention;

FIG. 5 is an enlarged, schematic cross-sectional view at a subsequent stage of manufacture in accordance with one embodiment of the present invention;

FIG. 6 is an enlarged, schematic cross-sectional view at a subsequent stage of manufacture in accordance with one embodiment of the present invention;

FIG. 7 is an enlarged, cross-sectional view of the structure shown in FIG. 1 at an earlier stage of manufacture in accordance with one embodiment of the present invention; and

FIG. 8 is a depiction of a system in accordance with one embodiment of the present invention.

### DETAILED DESCRIPTION

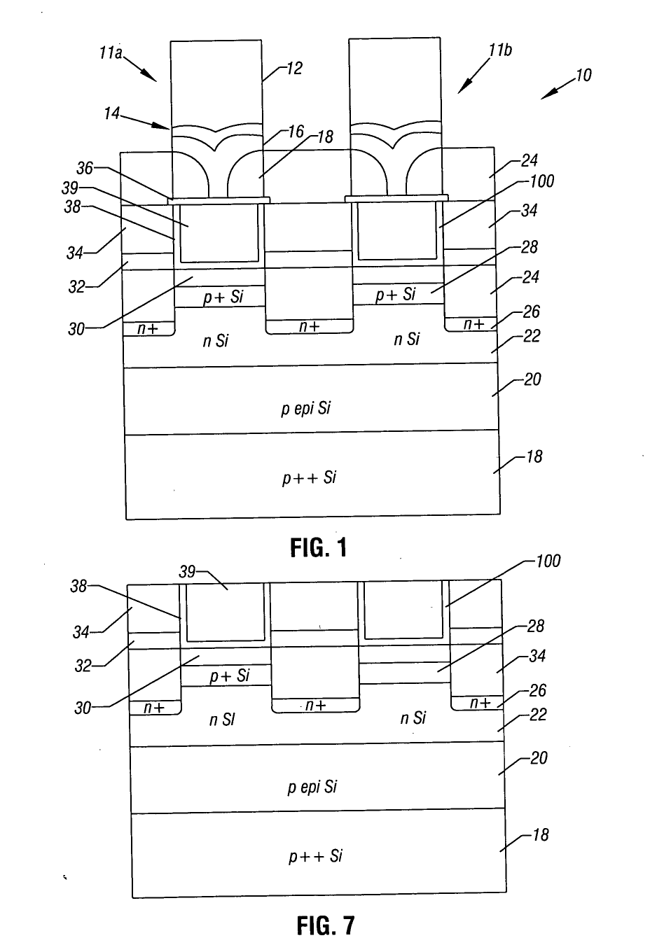

Referring to FIG. 1, a memory 10 may include two cells 11a and 11b. Isolation dielectric regions 24 with underlying doped regions 26 may be formed between adjacent memory cells 11. In some embodiments a number of cells 11 may be arranged in addressable rows and columns.

A substrate may include a lower substrate region 18, that in one embodiment may be highly doped p-type silicon, a middle substrate region 20, which in one embodiment may be p-type epitaxial material, and an upper substrate region 22, which may be n-type silicon in one embodiment of the present invention. Above the region 22 may be more heavily doped p-type silicon region 28 in one embodiment.

A lower electrode 30 over the region 28 may, for example, be formed of silicide such as cobalt silicide. Thus, in one embodiment, the region 22 may act as an address line that provides signals to the electrode 30 through the interface provided by the p-type silicon region 28.

A tubular, cup-shaped conductor 38 may be formed within an opening in a dielectric 34 to electrically couple the lower electrode 30. The cup-shaped conductor 38 may also be filled with a thermal barrier material 39, in one embodiment of the present invention. The upper edges of the cup-shaped conductor 38 electrically contact an electrode 36. The electrode 36 is in turn positioned under a memory material 16 positioned in a pore defined by sidewall spacers 18 in one embodiment. Above the memory material 16 is an upper electrode 14 that may be, for example, titanium or titanium nitride. Above the material 16 may be a conventional address line, such as an aluminum or copper conductor 12 in one embodiment.

The electrode 36 may, for example, be titanium aluminum nitride, titanium nitride, or titanium silicon nitride, to mention a few examples. The conductor 38 may be tungsten, titanium, titanium silicide, tantalum nitride, or titanium nitride, to mention a few examples. In one embodiment, the conductor 38 may be formed by chemical vapor deposition over a glue layer 100 such as titanium or titanium nitride, for example. Advantageously, the conductor 38 is formed of a material, such as tungsten, with good chemical mechanical planarization selectivity relative to the surrounding insulator 34.

The insulator 34 and material 39 may include an oxide, nitride, or a low K dielectric material, although the scope of the present invention is not limited in this respect. In other embodiments, the insulator 34 and material 39 may be an organic polymer material, a non-switching chalcogenide alloy, a sol-gel material, or any insulating material having lower thermal conductivity than an oxide material, such as high density plasma (HDP) oxide and atomic layer deposition (ALD) oxide. In general it is advantageous that the material 39 be an effective thermal insulator. In one embodiment the material 39 is less thermally conductive than a thermally grown oxide. The layer 32 may, in one embodiment, be silicon nitride.

In some embodiments of the present invention, the memory 10 has good thermal insulating characteristics in that the memory material 16 is thermally isolated by the thermal barrier material 39. In other words, heat loss downwardly is reduced by the imposition, below the memory material 16, of the thermal barrier material 39. At the same time, electrical continuity can be obtained from the electrode 30 to the electrode 36 through the conductor 38.

In one embodiment, the memory material 16 may be a non-volatile, phase change material. In this embodiment, the memory 10 may be referred to as a phase change memory. A phase change material may be a material having electrical properties (e.g. resistance) that may be changed through the application of energy such as, for example, heat, light, voltage potential, or electrical current. Examples of a phase change material may include a chalcogenide material or an ovonic material.

An ovonic material may be a material that undergoes electronic or structural changes and acts as a semiconductor when subjected to application of a voltage potential, an electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, the memory material 16 may be a chalcogenide element composition of the class of tellurium-germanium-antimony (TeₓGe_{y}Sb_{z}) material or a GeSbTe alloy, although the scope of the present invention is not limited to just these.

In one embodiment, if the memory material 16 is a non-volatile, phase change material, then memory material 16 may be programmed into one of at least two memory states by applying an electrical signal to memory material 16. The electrical signal may alter the phase of memory material 16 between a substantially crystalline state and a substantially amorphous state, wherein the electrical resistance of memory material 16 in the substantially amorphous state is greater than the resistance of memory material 16 in the substantially crystalline state. Accordingly, in this embodiment, memory material 16 may be adapted to be altered to one of at least two resistance values within a range of resistance values to provide single bit or multi-bit storage of information.

Programming of the memory material 16 to alter the state or phase of the material may be accomplished by applying voltage potentials to electrodes 36 and 14, thereby generating a voltage potential across memory material 16. An electrical current may flow through a portion of memory material 16 in response to the applied voltage potentials, and may result in heating of memory material 16.

This heating and subsequent cooling may alter the memory state or phase of memory material 16. Altering the phase or state of memory material 16 may alter an electrical characteristic of memory material 16. For example, the resistance of the material may be altered by altering the phase of the memory material 16. Memory material 16 may also be referred to as a programmable resistive material or simply a programmable material.

In one embodiment, a voltage potential difference of about three volts may be applied across a portion of memory material 16 by applying about three volts to electrode 14 and about zero volts to electrode 36. A current flowing through memory material 16 in response to the applied voltage potentials may result in heating of memory material 16. This heating and subsequent cooling may alter the memory state or phase of memory material 16.

In a “reset” state, the memory material 16 may be in an amorphous or semi-amorphous state and in a “set” state, the memory material 16 may be in a crystalline or semi-crystalline state. The resistance of memory material 16 in the amorphous or semi-amorphous state may be greater than the resistance of memory material 16 in the crystalline or semi-crystalline state. The association of reset and set with amorphous and crystalline states, respectively, is a convention. Other conventions may be adopted.

Due to electrical current, the memory material 16 may be heated to a relatively higher temperature to amorphisize memory material 16 and “reset” memory material 16 (e.g., program memory material 16 to a logic “0” value). Heating the volume of memory material 16 to a relatively lower crystallization temperature may crystallize memory material 16 and “set” memory material 16 (e.g., program memory material 16 to a logic “1” value). Various resistances of memory material 16 may be achieved to store information by varying the amount of current flow and duration through the volume of memory material 16.

The information stored in memory material 16 may be read by measuring the resistance of memory material 16. As an example, a read current may be provided to memory material 16 using electrodes 30 and 14, and a resulting read voltage across memory material 16 may be compared against a reference voltage using, for example, a sense amplifier (not shown). The read voltage may be proportional to the resistance exhibited by the memory cell. Thus, a higher voltage may indicate that memory material 16 is in a relatively higher resistance state, e.g., a “reset” state; and a lower voltage may indicate that the memory material 16 is in a relatively lower resistance state, e.g., a “set” state.

Embodiments of the present invention may be applicable to forming substantially planar structures in memory applications, as well as in a variety of other semiconductor applications. Thus, while FIG. 1 shows an example in the form of a phase change memory, the present invention is not necessarily so limited.

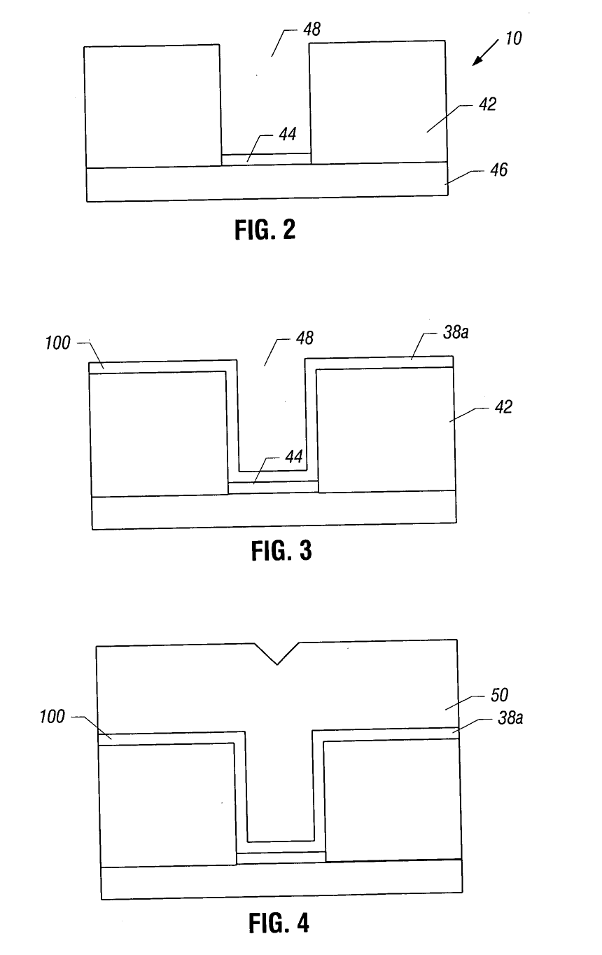

Referring to FIG. 2, a semiconductor substrate 46 may have a contact 44 formed thereon. An aperture 48 may be aligned with the contact 44 through an insulator or dielectric material 42. In one embodiment, the contact 44 may correspond to the electrode 30 of FIG. 1 and the substrate 46 may correspond to the substrate, including the regions 18, 20, 22, and 28 of FIG. 1. In such case, the dielectric 42 may correspond to the dielectric 34 in FIG. 1.

Referring to FIG. 3, a conductor 38a may be deposited into the aperture 46 and over the dielectric material 42. In one embodiment, the conductor 38a is a conformal layer such as chemical vapor deposited material such as tungsten. However, a variety of other materials may be utilized as well, including titanium materials, titanium nitride, and titanium aluminum nitride, to mention a few examples. The structure shown in FIG. 3 is then filled and covered with a thermally insulating material 50, such as high density plasma (HDP) oxide, as shown in FIG. 4. The material 50 fills the opening 48 and covers the entire extent of the conductor 38a in one embodiment.

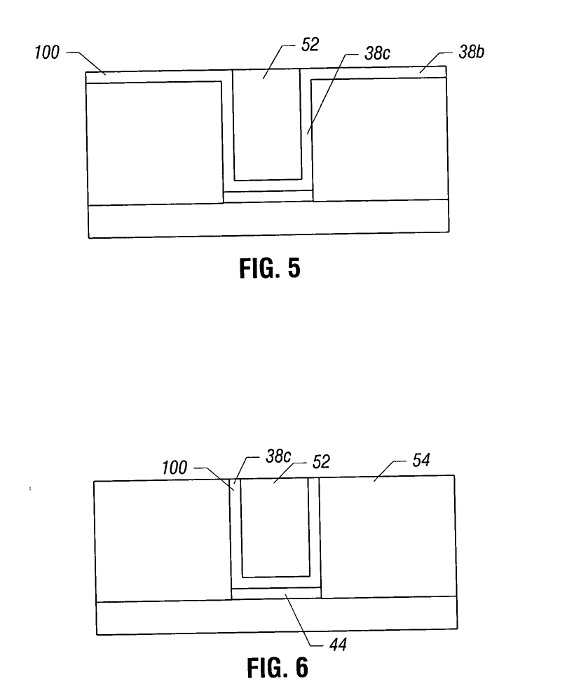

Referring to FIG. 5, the structure shown in FIG. 4 may then be subjected to a chemical mechanical polishing step to polish the structure down to the stop defined by the horizontal, substantially planar portion 38b of the conductor 38a. Without the planar portion 38b it would be difficult to stop the polishing at the right depth. This leaves a thermally insulating material 52 in the aperture 48 (FIG. 2). In one embodiment, the portion 38c of the conductor may be generally cup-shaped.

Next, the region 38b is removed, for example, by chemical mechanical planarization to form the substantially planar surface 54 as shown in FIG. 6. The substantially planar surface 54 is punctuated by the portion 38c of the conductor 38a.

Thus, referring to FIG. 7, the memory of FIG. 1 may be formed wherein the portion 38c in FIG. 6 corresponds to the conductor 38 in FIG. 7, the dielectric material 42 in FIG. 3 corresponds to the dielectric 34, the material 52 in FIG. 6 corresponds to the material 39, and the contact 44 in FIG. 6 corresponds to the electrode 30.

In some embodiments of the present invention, by covering the opening 48 in FIG. 2 with a conductive material and also lapping the conductive material over surrounding dielectric material as shown in FIG. 3, a convenient etch stop or chemical mechanical planarization stop is defined. The use of such a stop then enables precise control over the location of the resulting substantially planar surface 54 (FIG. 6).

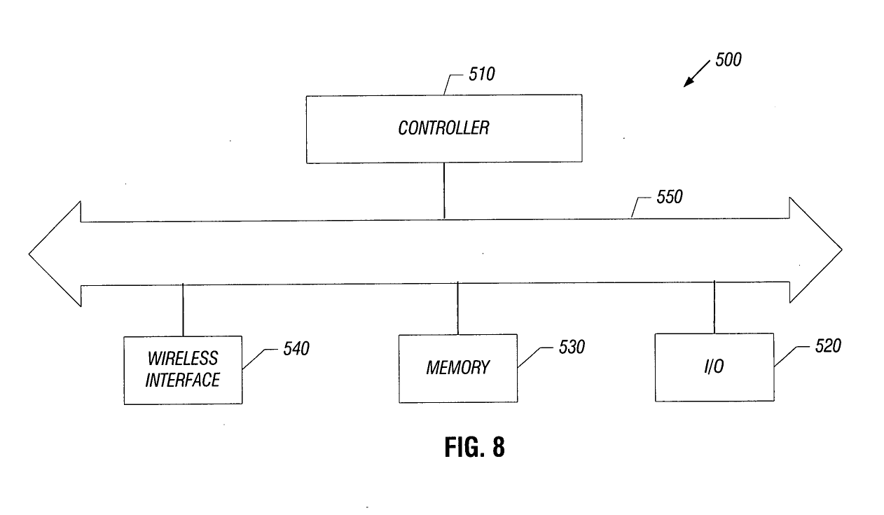

Turning to FIG. 8, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, and a wireless interface 540 coupled to each other via a bus 550. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise a volatile memory (any type of random access memory), a non-volatile memory such as a flash memory, and/or phase change memory that includes a memory element such as, for example, memory element 16 illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A semiconductor structure comprising:
a dielectric material formed over a substrate, said dielectric material having an aperture formed at least partially through said dielectric material;
a conductive material conformally coated over said dielectric and said aperture; and
a thermally insulating material formed within said aperture over said conductive material.

2. The structure of claim 1 wherein said conductive material is tungsten and said insulating material is a high density plasma oxide.

3. The structure of claim 1 wherein said conductive material has high polishing selectivity relative to said insulating material.

4. The structure of claim 1 wherein said insulating material has a lower thermal conductivity than thermally grown oxide.

5. A memory comprising:
an electrical contact coupled to a line in a substrate;
a tubular conductor extending upwardly from said contact, said tubular conductor being filled with a thermally insulating material;
a lower electrode coupled to said tubular electrode;
a memory material over said lower electrode; and
an upper electrode over said memory material.

6. The memory of claim 5 wherein said memory material is a phase change material.

7. The memory of claim 6 wherein said phase change material is a chalcogenide.

8. The memory of claim 5 wherein said tubular conductor is formed at least in part of tungsten.

9. The memory of claim 5 wherein said thermally insulating material has a thermal conductivity lower than that of thermally grown oxide.

10. A system comprising:
a processor-based device;
a wireless interface coupled to said processor-based device; and
a semiconductor memory coupled to said device, said memory including a substrate, said substrate including a conductive line, a contact formed over said substrate electrically coupled to said conductive line, and a memory element over said contact, said memory element coupled to said contact by a tubular conductor filled with a thermally insulating material.

11. The system of claim 10 wherein said memory material is a phase change material.

12. The system of claim 11 wherein said phase change material is a chalcogenide.

13. The system of claim 10 wherein said tubular conductor is formed at least in part of tungsten.

14. The system of claim 10 wherein said thermally insulating material has a thermal conductivity lower than that of thermally grown oxide.

15. The system of claim 10 including a glue layer between said aperture and said dielectric material and said conductive material.

16. The system of claim 15 wherein said glue layer includes titanium.
